(19) United States
(12) Patent Application Publication
(10) Pub. No.: US 2013/0159812 A1
(43) Pub. Date: Jun. 20, 2013

(54) MEMORY ARCHITECTURE FOR READ-MODIFY-WRITE OPERATIONS

(71) Applicants: Gabriel H. LOH, Bellevue, WA (US); James M. O'Connor, Austin, TX (US); Michael Ignatowski, Austin, TX (US); Nuwan S. Jayasena, Sunnyvale, CA (US); Bradford M. Beckmann, Redmond, WA (US)

(72) Inventors: Gabriel H. LOH, Bellevue, WA (US); James M. O'Connor, Austin, TX (US); Michael Ignatowski, Austin, TX (US); Nuwan S. Jayasena, Sunnyvale, CA (US); Bradford M. Beckmann, Redmond, WA (US)

(73) Assignee: ADVANCED MICRO DEVICES, INC., Sunnyvale, CA (US)

(21) Appl. No.: 13/328,393

(22) Filed: Dec. 16, 2011

(51) Int. Cl. H03M 13/09; G06F 11/10; G06F 12/00

(52) U.S. Cl. 714/758; 711/155; 711/E12.001; 714/E11.044

(57) ABSTRACT

According to one embodiment, a memory architecture implemented method is provided, where the memory architecture includes a logic chip and one or more memory chips on a single die, and where the method comprises: reading values of data from the one or more memory chips to the logic chip, where the one or more memory chips and the logic chip are on a single die; modifying, via the logic chip on the single die, the values of data; and writing, from the logic chip to the one or more memory chips, the modified values of data.

### BACKGROUND

Memory devices or packages, such as stacked memory, commonly have multiple chips with storage (or memory) and logic on each chip. Using multiple chips can increase the memory capacity of the memory devices. Other memory devices, including three-dimensional (3D)-stacked or 3D-integrated memory devices, such as a dynamic random-access memory (DRAM), may include storage or memory chips along with a separate logic chip that implements DRAM peripheral logic and other interface circuits.

### SUMMARY OF EMBODIMENTS

According to one embodiment, a memory architecture implemented method, where the memory architecture includes a logic chip and one or more memory chips on a single die, and where the method can include: reading values of data from the one or more memory chips to the logic chip, where the one or more memory chips and the logic chip are on a single die; modifying, via the logic chip on the single die, the values of data; and writing, from the logic chip to the one or more memory chips, the modified values of data.

According to another embodiment, a stacked memory architecture implemented on a single die may be provided, where the stacked memory architecture may include: one or more memory layers; and a logic layer, where the logic layer can be vertically stacked with the one or more memory layers, and where the logic layer can include logic instructions to perform a read-modify-write operation within the single die.

According to another embodiment, a side-split memory architecture implemented on a single die may be provided, where the side-split memory architecture may include: one or more memory layers; and a logic layer, where the logic layer is horizontally separated from the one or more memory layers, and where the logic layer includes logic instructions to perform a read-modify-write operation within the single die.

According to one embodiment, an error correcting code memory is provided that may include: one or more memory chips formed on a die; and a logic chip formed on the die with the one or more memory chips, where the logic chip is to perform at least one of a first operation or a second operation, where the logic chip, when performing the first operation, can be used to: read error correction code protected data from at least one of the one or more memory chips, modify the error correcting code protected data, compute new error correcting code parity bits associated with the error correcting code protected data, and write the modified error correcting code protected data and the new error correcting code parity bits to the one or more memory chips; and where the logic chip, when performing the second operation, is to: read error correction code protected data from at least one of the one or more memory chips, determine whether an error is detected, modify the data and/or error correcting code parity bits when an error is detected, and write the modified data and/or error correcting code parity bits to the one or more memory chips.

### BRIEF DESCRIPTION OF THE DRAWINGS

The accompanying drawings, which are incorporated in and constitute a part of this specification, illustrate one or more embodiments described herein and, together with the description, explain these embodiments. In the drawings:

FIGS. 1A and 1B are diagrams of example memory architectures according to embodiments described herein;

FIG. 2 is an illustration of example components of a device that may include example memory architectures;

FIG. 3 is an illustration of an example memory device and central processing unit (CPU) communication path diagram for a read-modify-write operation; and

FIG. 4 is an illustration of an example memory architecture and CPU communication path diagram for a read-modify-write operation.

### DETAILED DESCRIPTION

The following detailed description refers to the accompanying drawings. The same reference numbers in different drawings may identify the same or similar elements. Also, the following detailed description does not limit the claims.

Memory architecture of a memory device is provided that includes one or more memory chips (e.g., storage chips or layers) and a separate logic chip (e.g., logic specific chip or layer) on a single die (e.g., die-split memory, such as a stacked memory or a side-split memory). By providing one or more memory chips and a separate logic chip, the memory architecture can be used to perform different operations from a memory device with a single die that includes storage and logic on the chip.

In one implementation, a logic operation can be run by the separate logic chip to take advantage of logic located on the separate logic chip in the memory architecture. For example, the logic, of the logic chip of the memory architecture, can perform a read-modify-write operation that can occur within the memory architecture without transferring data to or from a processor outside of the memory architecture.

In another implementation, a logic chip can be manufactured using a different process from storage chips or memory chips. For example, a logic chip can be manufactured with performance, power and energy provisions to expressly benefit logic chips rather than storage chips or memory chips with logic and storage thereon, which are primarily manufactured for cell density and leakage control.

The memory architecture may be included in a memory device, such as a random access memory (RAM), a static RAM (SRAM), a dynamic RAM (DRAM), error-correcting code (ECC) memory, a read only memory (ROM), a phase-change memory, a memristor, another types of static storage device that may store static information and/or instructions, and/or another types of dynamic storage device that may store information and instructions. In one example embodiment, the memory device may include an ECC memory.

The terms “component” and “device,” as used herein, are intended to be broadly construed to include hardware (e.g., a processor, a microprocessor, an application-specific integrated circuit (ASIC), a field-programmable gate array (FPGA), a chip, a memory device (e.g., ROM, RAM, etc.), etc.) or a combination of hardware and software (e.g., a processor, microprocessor, ASIC, etc. executing software contained in a memory device).

The memory architecture with the one or more memory chips and the separate logic chip may include fewer components, different components, differently arranged components, or additional components than those described herein. Alternatively, or additionally, one or more components of memory architecture may perform one or more other tasks described as being performed by one or more other components of memory architecture.

Memory architecture, as used herein, can include a memory device, chip, or arrangement of one or more memory chips (or layers) with a separate logic chip (or layer) on a single die. Memory architecture can include stacked memory, split memory, such as side-split memory, or any configuration of memory chips with a separate logic chip on a single die.

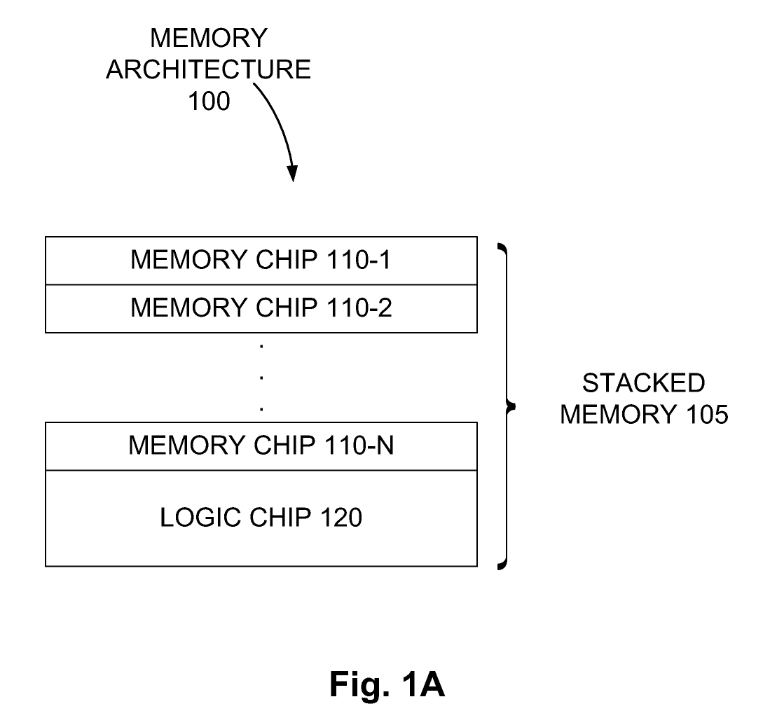

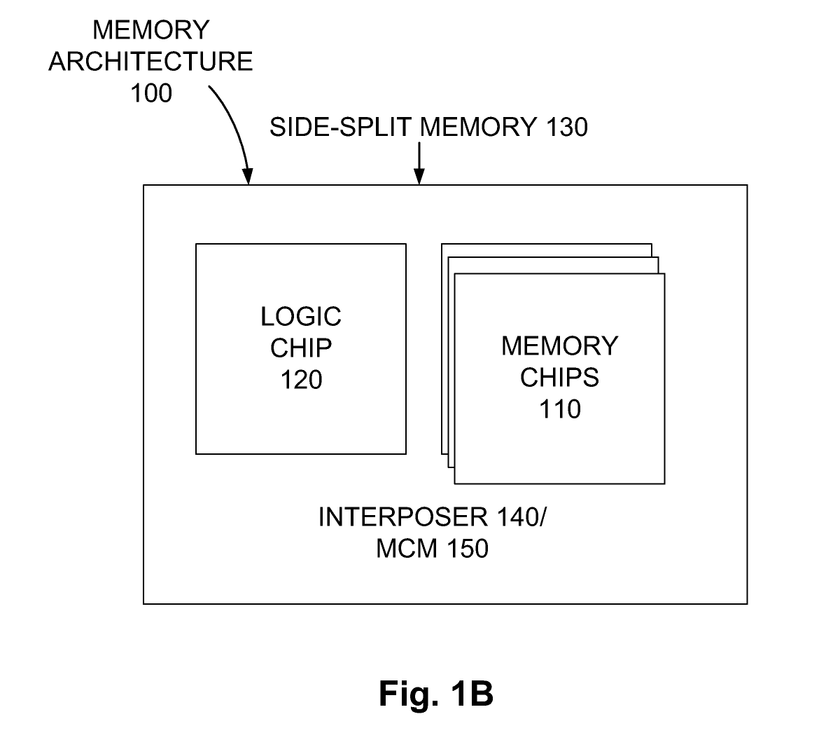

As illustrated in FIG. 1A, memory architecture 100 can include stacked memory 105, where one or more memory chips 110-1, 110-2 . . . 110-N (N≧1) (collectively referred to herein as “memory chips 110,” and, in some instances, singularly as “memory chip 110”) are stacked vertically with a separate logic chip 120. Logic chip 120 is illustrated at the bottom of stacked memory 105, but can be located anywhere in the stacked memory 105 including the top or middle, above or between memory chips 110.

Memory chips 110 may be layers or chips provided for storage. Memory chips 110 may include a small block of semiconductor material (e.g., a die) on which a memory circuit is fabricated. In one example embodiment, memory chips 110 may include memory formed from multiple layers of DRAM dies.

Logic chip 120 may include a logic layer or logic designated chip and may be a semiconductor material that implements peripheral logic, input/output circuits, discrete Fourier transform circuits (DFT), and/or other circuits. In one example embodiment, logic chip 120 may include additional capacity for implementing additional logic or instructions.

Another example of memory architecture 100, as illustrated in FIG. 1B, includes side-split memory 130, where memory chip 110 can be placed horizontally from logic chip 120 on interposer 140 or multi-chip module (MCM) 150 on a single die. Logic chip 120 is illustrated as adjacent to memory chips 110 on an interposer 140 or MCM 150, but logic chip 120 and memory chips 110 can be placed in any position on interposer 140 or MCM 150. Memory chips 110 are illustrated as a stack of memory chips 110, but memory chips 110 can include more memory chips 110 in any position on interposer 140 or MCM 150 including memory chips 110 positioned horizontally adjacent to other memory chips 110 or logic chip 120, such as individual or stacked memory chips 110 in two or more horizontally adjacent positions to logic chip 120.

Interposer 140 can be any substrate to which components can be attached prior to attaching the interposer to a substrate. For example, as illustrated in FIG. 1B, logic chip 120 and memory chips 110 can be attached to interposer 140 and interposer 140 can be attached to a substrate. Interposer 140 can have wired, wireless, or a combination of wired and wireless interconnections between logic chip 120 and memory chips 110. In one implementation, interposer 140 can be a silicon substrate or another dielectric substrate.

MCM 150 can be a package where multiple chips, such as memory chips and logic chips, can be packaged onto a substrate to form a module. For example, as illustrated in FIG. 1B, memory chips 110 and logic chip 120 can be attached to MCM 150 to form side-split memory 130. In one implementation, MCM 150 substrates can be printed circuit boards (PCB), silicon, or another dielectric substrate.

While implementations have been described as being employed in memory architecture 100, which can include logic chip 120 and memory chips 110, there may be other physical manifestations that can also be covered. Memory architecture 100, referred to here, can also include one or more stacks of memory chips 110 and/or logic chips 120, one or more such stacks of memory chips 110 and/or logic chips 120 making up part of a larger memory system, or one or more such stacks of memory chips and/or logic chips serving as a cache for a larger memory system.

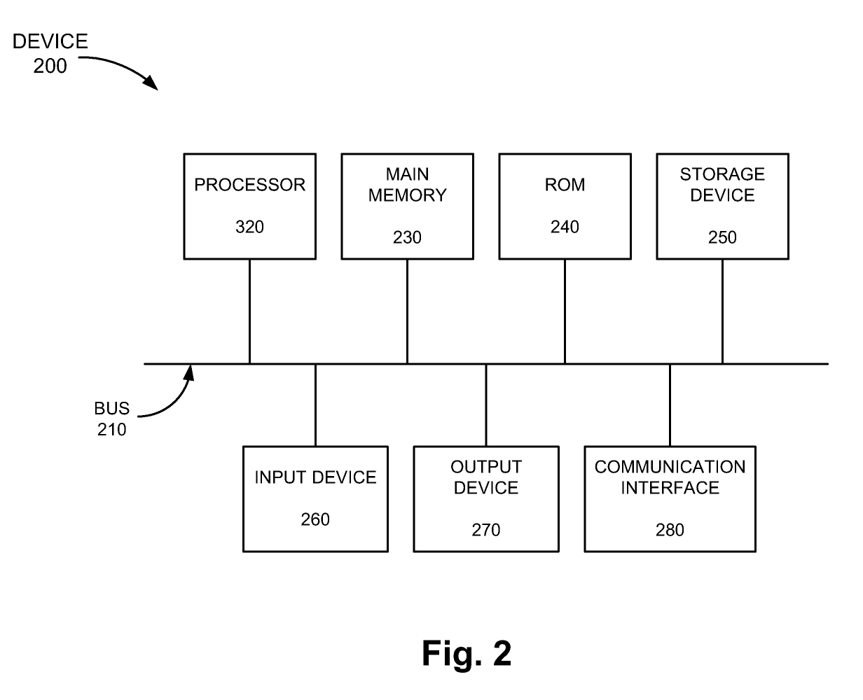

FIG. 2 is a diagram of example components, of a device that may use memory devices with memory architecture 100. Device 200 may include any computation or communication device that utilizes a memory device, such as a personal computer, a desktop computer, a laptop computer, a tablet computer, a server device, a radiotelephone, a personal communications system (PCS) terminal, a personal digital assistant (PDA), a cellular telephone, a smart phone, and/or another type of computation or communication device.

As illustrated in FIG. 2, device 200 may include a bus 210, a processing unit 220, a main memory 230, a ROM 240, a storage device 250, an input device 260, an output device 270, and/or a communication interface 280. One or more of these components may include memory devices using memory architecture 100, such as processing unit 220, main memory 230, ROM 240, or storage device 250.

Bus 210 may include a path that permits communication among the components of device 200. Processing unit 220 may include one or more processors (e.g., multi-core processors), microprocessors, ASICS, FPGAs, a CPU, a graphical processing unit (GPU), or other types of processing units that may interpret and execute instructions. In one embodiment, processing unit 220 may include a single processor that includes multiple cores.

Main memory 230 may include a RAM, a DRAM, and/or another type of dynamic storage device that may store information and instructions for execution by processing unit 220. ROM 240 may include a ROM device or another type of static storage device that may store static information and/or instructions for use by processing unit 220. Storage device 250 may include a magnetic and/or optical recording medium and its corresponding drive. In one embodiment, main memory 230, ROM 240, and/or storage device 250 may incorporate memory architecture 100.

Input device 260 may include a mechanism that permits an operator to input information to device 200, such as a keyboard, a mouse, a pen, a microphone, voice recognition and/or biometric mechanisms, a touch screen, etc. Output device 270 may include a mechanism that outputs information to the operator, including a display, a printer, a speaker, etc. Communication interface 280 may include any transceiver-like mechanism that enables device 200 to communicate with other devices and/or systems. For example, communication interface 280 may include mechanisms for communicating with another device or system via a network.

Although FIG. 2 shows example components of device 200, in other embodiments, device 200 may include fewer components, different components, differently arranged components, or additional components than depicted in FIG. 2. Alternatively, or additionally, one or more components of device 200 may perform one or more other tasks described as being performed by one or more other components of device 200.

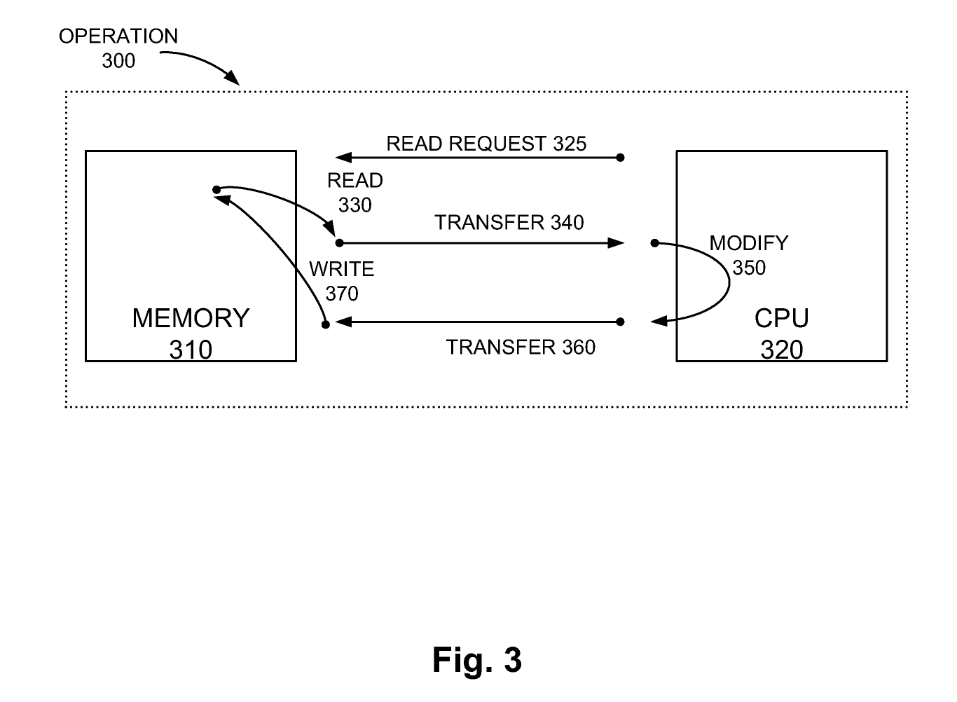

FIG. 3 is a diagram of example operation 300 capable of being performed by memory 310 and CPU 320. Memory 310 can include a memory device with memory storage components and peripheral logic and circuits on a single silicon chip or a memory device with memory architecture 100.

Computer programs can perform operation 300. Operation 300 can include a read-modify-write operation using memory 310 and CPU 320. Operation 300 can include CPU 320 sending a read request 325 to memory 310. Memory 310 can read a value of data 330 from memory 310 and transfer the value 340 to CPU 320. CPU 320 can modify the value 350 and transfer the modified value 360 back to memory 310. Memory 310 can write the modified value 370. Operation 300 includes at least two data transfers between memory 310 and CPU 320, which can consume time, energy and bandwidth, as well as additional time and energy spent navigating through on-chip memory hierarchy.

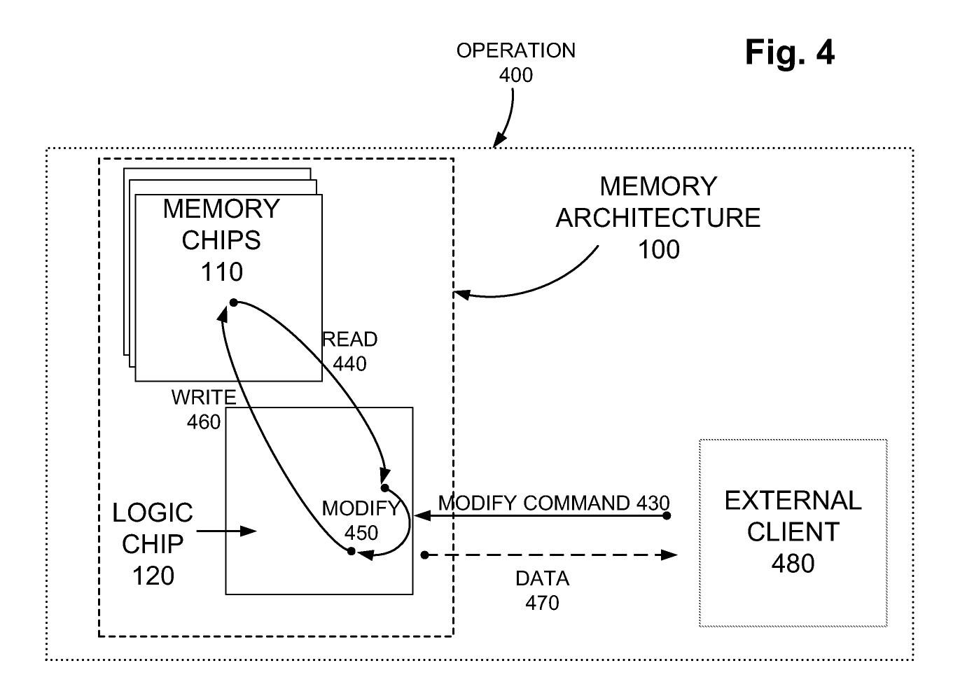

FIG. 4 is a diagram of example operation 400 capable of being performed by a memory device with memory architecture 100 that includes memory chips 110 and a separate logic chip 120 on a single die. Memory architecture 100 can include side-split memory 130, stacked memory 105, or any other configuration with memory chips 110 and a separate logic chip 120 on a single die.

Computer programs can perform example operation 400 using a memory device with memory architecture 100. In example operation 400, a read-modify-write operation can be performed by memory chips 110 and logic chip 120.

In example operation 400, an external client 480, which is external to memory architecture 100, can be in communication with memory architecture 100. External client 480 can include any processor or logic-providing device that is external to memory architecture 100, such as a processor (e.g., CPU 320) or any other external client 480 that can provide instructions to memory architecture 100.

In example operation 400, a read-modify-write operation can be performed with or without interaction from external client 480. One example of a read-modify-write operation with interaction from external client 480 is illustrated in FIG. 4, where external client 480 may provide modify command 430 and logic chip 120 can optionally send data 470 to external client 480.

One example of a read-modify-write operation that can be performed without interaction from external client 480 is an error correction code (ECC) memory with memory architecture 100, which can perform read-modify-write operations without interaction from external client 480.

As illustrated in FIG. 4, read-modify-write operation 400 can include reading values of data 440 from memory chips 110 to logic chip 120. Operation 400 can include modifying the values 450 by logic chip 120. Unlike operation 300, operation 400 modifies the values 450 within logic chip 120 on a single die with memory chips 110 rather than using a separate transfer 340 to CPU 320, where modifying the values 350 can occur. Operation 400 also does not use a second transfer 360 before writing to memory 370, unlike operation 300. Rather, operation 400 can write the modified values of data 460 to memory chips 110 directly from logic chip 120.

In one implementation, logic chip 120 can be provided with instructions on how to modify values of data from external client 480. External client 480 can provide a modify command 430 to logic chip 120 initially to begin a read-modify-write operation 400. For example, a computer program can include a modify command 430 that external client 480 can send to logic chip 120 requesting modification of a value of data from memory chips 110.

External client 480 can also optionally receive a completion code or other data 470 for certain operations. For example, a computer program can request external client 480 to send a modify command 430 to logic chip 120, and logic chip 120 can send a completion code or other data 470 to external client 480 upon completion of instructions contained in the modify command 430 sent by external client 480.

By providing a read-modify-write operation that can operate within memory architecture 100 and can be controlled by logic chip 120, read-modify-write operations 400 can be performed more quickly because data does not need to be sent to external client 480 (or another client) for modification (e.g., transfer the value 340 to CPU 320 in FIG. 3), and also does not need to be sent back (e.g., transfer the value 360 from CPU 320 in FIG. 3). Overall, power and energy can be saved by avoiding the transfers of data external to memory architecture 100.

Although FIG. 4 shows example operation 400 capable of being performed by components of memory architecture 100, in other embodiments, memory architecture 100 may perform fewer operations, different operations, or additional operations than depicted in FIG. 4. Alternatively, or additionally, one or more components of memory architecture 100 may perform one or more other operations described as being performed by one or more other components of memory architecture 100.

In one example implementation, multi-threaded programs can be provided to memory architecture 100. Many multi-threaded programs require synchronization primitives, such as atomic increments, atomic test-and-set, atomic test-and-swap, atomic swap, and atomic logical operations on memory, such as a logical AND, OR, Exclusive-OR, and others. Multi-threaded programs can be implemented through locking/blocking support in the memory hierarchy, which can add significant complexity to the memory coherence protocols. Instead, these operations can be directly supported by logic chip 120 of memory architecture 100. For example, an atomic increment command may be provided by memory architecture 100 that accepts an address and an increment amount. Upon receiving the command, memory architecture 100 can load the value from the specified address, can increment the value by the increment amount, and can store a modified value back to the memory, while ensuring that no other requests (read, write, or another atomic read-modify-write operation) access the same memory location at the same time.

Embodiments could support any one or more atomic update operations. Furthermore, the synchronization primitives can be implemented as either new instructions or could simply leverage existing instructions and identify the data locations as uncacheable. In essence, one view of this embodiment could be as an efficient implementation of synchronization for uncacheable data when multi-chip memory can be stacked on logic chip 120.

While the embodiment discusses uncacheable data, these operations could also be implemented for cacheable data not currently cached in a lower level cache for the requesting CPU (e.g., one with shorter access time than memory architecture 100). In such a case, invalidation operations could be sent to delete any copy currently being cache by other CPUs. Such an implementation could make implementations herein useable with memory architecture 100 that are used as a cache for a larger memory system.

In another implementation, applications using conditional writes can be used with memory architecture 100. For example, many applications, particularly multi-media applications, make use of conditional writes. Conditional writes can utilize read-modify-write operations that can read a value from memory, test the value against some condition, and then if the condition is true, can write a new value into the memory. In one embodiment, logic chip 120 of memory architecture 100 can implement a circuit that performs a conditional-write operation. One example can be saturation, where a command can provide a memory address, a threshold value, and a saturation value. Logic chip 120 can load a value from an addressed memory location and compares it to a threshold value. If the value is greater than the threshold value, then the saturation value can be written into the memory instead, and in either case the final value can be written back to the memory. Other embodiments may include Z-test (e.g., in computer graphics, comparing a Z (depth) value of a new pixel with a Z buffer (or depth buffer) value of a present pixel, and writing the Z value if the new pixel has a smaller value than (or is “in front of”) the present pixel), absolute value, positive or negative comparisons (either greater than a threshold or less than a threshold), text manipulations (e.g., convert lower case text to uppercase text), or any other conditional-write operations.

General conditional-write operations can be used to support transactional memory, where a memory-write can manifest itself as a conditional write where the condition to be checked can be whether a transaction had any conflicts. Embodiments could support any conditional write operation.

Memory architecture 100 can also be used with ECC memory. In one implementation, logic chip 120 of memory architecture 100 can be used to directly support the functionality of ECC memory. For example, a write command can cause the circuit to read data from memory chips 110, modify the data of ECC protected data, compute new ECC parity bits, and write new data and new ECC parity bits to memory chips 110 without any external assistance or interaction from a CPU or other external client outside of memory architecture 100.

Additionally, or alternatively, logic chip 120 of memory architecture 100 can be used for an ECC read command. A read command can cause logic chip 120 to read data from memory, and if an error is detected, logic chip 120 can correct or modify the data and/or ECC bits, and can write the corrected data back to memory.

Other embodiments may include compression (e.g., read compressed data, decompress-modify-recompress, write back), encryptions (e.g., read encrypted data, decrypt-modify-encrypt, write back), or any other form of encoding. Embodiments could support any one or a plurality of encoded read-modify-write operations.

Beyond supporting synchronization and ECC operations at the memory block level or smaller granularity, logic chip 120 of memory architecture 100 can be leveraged to support higher granular synchronized operations. For example, an operating system can map a physical page to a new virtual page, and can “zero out” the page for security/privacy reasons. In order to avoid occupying a CPU for this task, sometimes a direct memory access (DMA) engine can perform this operation in the background.

DMA operations can consume off-stack bandwidth and can require software synchronization to confirm completion. In order to avoid this off-stack bandwidth consumption and additional software synchronization, logic chip 120 of memory architecture 100 can lock down an entire page (e.g., 4 KB for a page) and perform these operations internally within the stack. This can be viewed as an optimized or a degenerate case of read-modify-write because locations can be written with the value zero, so the read operation can be skipped. This can also be applied, for example, to memset operations (e.g., operations that set all locations of a buffer to a repeated byte of the same constant value, which could be some value other than zero). When writing a value to a block of memory, it is also possible to read the memory locations first and only write those bits that need to be changed back into the memory. This can reduce the energy used by the write operation.

While many of the examples above discuss read-modify-write operations applied to singular memory locations, embodiments could also support vector or Single Instruction, Multiple Data (SIMD) versions of these operations that operate on multiple memory locations (e.g., from two or four consecutive locations, to a full page (e.g., 4 KB) or more). Such implementations could also enable additional operations, such as search, compare, find min/max values, and sum all values.

Implementations can also include multiple types of interfaces. In one embodiment, read-modify-write operations may be issued using a single compound command (e.g., a single compound command that causes the row containing address X to be read into the memory row buffer, incremented, and then written back), or the operations may be issued using a sequence of commands, or a combination of single and sequence commands.

In one implementation, a method including logic-layer read-modify-write operations for all memory technologies can be included. While DRAM can be one memory technology, implementations can be applied to memory systems implemented with one or more of DRAM, SRAM, eDRAM, phase-change memory, memristors, STT-MRAM (Spin Transfer Torque-Magnetoresistive random access memory), or other memory technologies.

In one implementation, logic chip 120 can be manufactured using a different process from storage chips or memory chips that include storage and memory on the chip. Accordingly, logic chip 120 can be manufactured with performance, power, and energy provisions. For example, new chips can be manufactured that are optimized for logic chip performance, power, and energy.

Systems and/or methods described herein can include functionalities where circuits in logic chip 120 of a memory architecture 100, separate from memory chips 110 but within the same memory architecture 100, can perform read-modify-write operations without sending data to an external client (although memory architecture 100 can still support this mode of operation). By providing system and/or methods described herein, both performance and power/energy efficiency can be improved.

The foregoing description of embodiments provides illustration and description, but is not intended to be exhaustive or to limit the claims to the precise form disclosed. Modifications and variations are possible in light of the above disclosure or may be acquired from practice of the claims.

Further, certain embodiments described herein may be implemented as “logic” that performs one or more functions. This logic may include hardware, such as a processor, an ASIC, or a FPGA, or a combination of hardware and software.

Even though particular combinations of features are recited in the claims and/or disclosed in the specification, these combinations are not intended to limit the disclosure of the possible implementations. In fact, many of these features may be combined in ways not specifically recited in the claims and/or disclosed in the specification. Although each dependent claim listed below may directly depend on only one other claim, the disclosure includes each dependent claim in combination with every other claim in the claim set.

No element, block, or instruction used in the present application should be construed as critical or essential unless explicitly described as such. Also, as used herein, the article “a” is intended to include one or more items. Where only one item is intended, the term “one” or similar language is used. Further, the phrase “based on” is intended to mean “based, at least in part, on” unless explicitly stated otherwise.

What is claimed is:

1. A memory architecture implemented method, where the memory architecture includes a logic chip and one or more memory chips on a single die and where the method comprises:
reading values of data from the one or more memory chips to the logic chip, where the one or more memory chips and the logic chip are on a single die;
modifying, via the logic chip on the single die, the values of data; and
writing, from the logic chip to at least one of the one or more memory chips, the modified values of data.

2. The memory architecture implemented method of claim 1, further comprising:
receiving a modify command from an external client, where the modify command instructs the logic chip regarding modifying the values of data, and where the external client is not on the single die with the one or more memory chips and the logic chip.

3. The memory architecture implemented method of claim 2, further comprising:
sending a completion code to the external client, where the completion code is sent by the logic chip in response to completion of instructions contained in the modify command.

4. The memory architecture implemented method of claim 3, where:
the modify command includes an atomic increment command, and where:
reading values of data includes reading the values of data from a specified address,
modifying the values of data includes modifying the values of data by incrementing the values by an increment amount specified by the atomic increment command,
writing the modified values of data includes writing the incremented values, and
sending the completion code includes sending an atomic increment completion code to the external client.

5. The memory architecture implemented method of claim 1, where the values of data comprise error correction code protected data, and where:
modifying the values of data includes modifying the values of data and computing new error correcting code parity bits, and
writing the modified values of data includes writing the modified values of data and the new error correcting code parity bits to at least one of the one or more memory chips.

6. The memory architecture implemented method of claim 1, where the method is initiated using a single compound command, a sequence of commands, or a combination of single and sequence commands.

7. The memory architecture implemented method of claim 1, further comprising:
searching, by the logic chip, in memory of at least one of the one or more memory chips for values of data,
comparing, by the logic chip, values of data in at least one of the one or more memory chips,
searching, by the logic chip, values of data in at least one of the one or more memory chips to find a minimum and/or maximum value, or
summing, by the logic chip, a set of the values of data in at least one of the one or more memory chips.

8. A stacked memory architecture implemented on a single die, the stacked memory architecture comprising:
one or more memory layers; and
a logic layer, where the logic layer is vertically stacked with the one or more memory layers, and where the logic layer includes logic instructions to perform a read-modify-write operation within the single die.

9. The stacked memory architecture of claim 8, where the logic layer is to execute the logic instructions to:
read, from at least one of the one or more memory layers, values of data;
modify, via the logic layer, the values of data;
write, from the logic layer to at least one of the one or more memory layers, the modified values of data.

10. The stacked memory architecture of claim 9, where the logic layer is to execute the logic instructions to further:
receive a modify command from an external client, where the external client is not on the single die with the one or more memory chips and the logic chip, and where the modify command instructs the logic layer regarding the modifying of the values of data, and/or
send a completion code to the external client, where the external client is not on the single die with the one or more memory chips and the logic chip, and where the completion code is sent by the logic layer in response to completion of instructions contained in the modify command from the external client.

11. The stacked memory architecture of claim 10, where the logic layer is to execute the logic instructions from the modify command from the external client, where the modify command is an atomic increment command, and where logic layer is to execute the logic instruction to:
modify the values of data by an atomic increment amount, and
send an atomic increment completion code to the external client.

12. The stacked memory architecture of claim 9, where the stacked memory architecture comprises error correction code memory, and where the logic layer is to execute logic instructions to:
modify the values of data and compute new error correcting code parity bits, and
write the modified data and new error correcting code parity bits to at least one of the one or more memory layers.

13. The stacked memory architecture of claim 8, where the logic layer is to execute logic instructions to further:
search, by the logic layer, in memory of at least one of the one or more memory layers for values of data,
compare, by the logic layer, the values of data in at least one of the one or more memory layers,
search, by the logic layer, the values of data in at least one of the one or more memory layers to find a minimum and/or maximum value, or
sum, by the logic layer, the values of data in at least one of the one or more memory layers.

14. A side-split memory architecture implemented on a single die, the side-split memory architecture comprising:
one or more memory layers; and
a logic layer, where the logic layer is horizontally separated from the one or more memory layers, and where the logic layer includes logic instructions to perform a read-modify-write operation within the single die.

15. The side-split memory architecture of claim 14, where the logic layer is to execute the logic instructions to:
read, from at least one of the one or more memory layers, values of data;
modify, via the logic layer, the values of data;
write, from the logic layer to at least one of the one or more memory layers, the modified values of data.

16. The side-split memory architecture of claim 15, where the logic layer is to execute the logic instructions to further:
receive a modify command from an external client, where the external client is not on the single die with the one or more memory chips and the logic chip, and where the modify command instructs the logic layer regarding the modifying of the values of data, and/or
send a completion code to the external client, where the external client is not on the single die with the one or more memory chips and the logic chip, and where the completion code is sent by the logic layer in response to completion of instructions contained in the modify command from the external client.

17. The side-split memory architecture of claim 16, where the logic layer is to execute the logic instructions from the modify command from the external client, where the modify command is an atomic increment command, and where logic layer is to execute the logic instruction to:
modify the values of data by an atomic increment amount, and
send an atomic increment completion code to the external client.

18. The side-split memory architecture of claim 15, where the stacked memory architecture comprises error correction code memory, and where the logic layer is to execute logic instructions to:
modify the values of data and compute new error correcting code parity bits, and
write the modified data and new error correcting code parity bits to at least one of the one or more memory layers.

19. The side-split memory architecture of claim 14, where the logic layer is to execute logic instructions to further:
search, by the logic layer, in memory of at least one of the one or more memory layers for values of data,
compare, by the logic layer, the values of data in at least one of the one or more memory layers,
search, by the logic layer, the values of data in at least one of the one or more memory layers to find a minimum and/or maximum value, or
sum, by the logic layer, the values of data in at least one of the one or more memory layers.

20. An error correcting code memory, comprising:
one or more memory chips formed on a die; and
a logic chip formed on the die with the one or more memory chips, where the logic chip is to perform at least one of a first operation or a second operation, where the logic chip, when performing the first operation, is to:
read error correction code protected data from at least one of the one or more memory chips,
modify the error correcting code protected data,
compute new error correcting code parity bits associated with the error correcting code protected data, and
write the modified error correcting code protected data and the new error correcting code parity bits to at least one of the one or more memory chips; and
where the logic chip, when performing the second operation, is to:
read error correction code protected data from at least one of the one or more memory chips,
determine whether an error is detected,
modify the data and/or error correcting code parity bits when an error is detected, and
write the modified data and/or error correcting code parity bits to at least one of the one or more memory chips.
